(19) United States
(12) Patent Application Publication
(10) Pub. No.: US 2005/0069641 A1
(43) Pub. Date: Mar. 31, 2005

(54) Method for depositing metal layers using sequential flow deposition

(75) Inventors: Tsukasa Matsuda, Kitakoma-gun (JP); Taro Ikeda, Nirasaki-City (JP); Tatsuo Hatano, Ryuo-City (JP); Mitsuhiro Tachibana, Nakakoma-gun (JP); Hideaki Yamasaki, Kofu-City (JP); Gert J. Leusink, Saltpoint, NY (US); Fenton R. McFeely, Ossining, NY (US); Sandra G. Malhotra, Beacon, NY (US); Andrew H. Simon, Fishkill, NY (US); John J. Yurkas, Stamford, CT (US)

Correspondence Address: PILLSBURY WINTHROP, LLP, P.O. BOX 10500, MCLEAN, VA, 22102, US

(73) Assignees: Tokyo Electron Limited, Tokyo (JP); International Business Machines Corporation, Armonk, NY (US)

(21) Appl. No.: 10/673,910

(22) Filed: Sep. 30, 2003

(51) Int. Cl. B05D 3/02; C23C 16/00

(52) U.S. Cl. 427/226; 427/248.1

(57) ABSTRACT

A method for depositing metal layers with good surface morphology using sequential flow deposition includes alternately exposing a substrate in a process chamber to a metal-carbonyl precursor gas and a reducing gas. During exposure with the metal-carbonyl precursor gas, a thin metal layer is deposited on the substrate, and subsequent exposure of the metal layer to the reducing gas aids in the removal of reaction by-products from the metal layer. The metal-carbonyl precursor gas and a reducing gas exposure steps can be repeated until a metal layer with a desired thickness is achieved. The metal-carbonyl precursor can, for example, be selected from W(CO)₆, Ni(CO)₄, Mo(CO)₆, Co₂(CO)₈, Rh₄(CO)₁₂, Re₂(CO)₁₀, Cr(CO)₆, and Ru₃(CO)₁₂.

### FIELD OF THE INVENTION

The present invention relates to semiconductor processing, and more particularly, to a method for depositing metal layers from metal-carbonyl precursors.

### BACKGROUND OF THE INVENTION

The introduction of copper (Cu) metal into multilayer metallization schemes for manufacturing integrated circuits, can necessitate the use of diffusion barriers/liners to promote adhesion and growth of the Cu layers, and to prevent diffusion of Cu into the dielectric materials. Barriers/liners that are deposited onto dielectric materials can include refractive materials such as tungsten (W), molybdenum (Mo), and tantalum (Ta), that are non-reactive and immiscible with Cu and can offer low electrical resistivity. Current integration schemes that integrate Cu metallization and dielectric materials can require barrier/liner deposition processes at substrate temperatures between about 400° C. and about 500° C., or lower.

W layers can be formed in a thermal chemical vapor deposition (TCVD) process by thermally decomposing a tungsten-halide precursors, e.g., tungsten hexafluoride (WF₆), in the presence of a reducing gas such as hydrogen, silane, dichlorosilane, etc. A drawback to using tungsten-halide precursors is incorporation of halide by-products in the W layer that can degrade the material properties of the W layer.

Non-halogen containing tungsten precursors such as a tungsten-carbonyl precursor, can be used to alleviate the abovementioned drawbacks associated with tungsten-halide precursors. However, material properties of W layers that are deposited by thermal decomposition of metal-carbonyl precursors (e.g., W(CO)₆), can deteriorate due to incorporation of CO reaction by-products into the thermally deposited W layers. Incorporation of CO reaction by-products can increase the (electrical) resistivity of the W layers and lead to poor surface morphology due to abnormal growth of W nodules (particles) on the surface of the W layer and/or in the W layer. The formation of W nodules can affect the etch behavior of the W layer and affect integration of W layers when manufacturing integrated circuits, for example, by creating a shadow effect when sputter depositing a metal layer (e.g., copper) on the W layer.

### SUMMARY OF THE INVENTION

A method is provided for depositing a metal layer on a substrate using sequential flow deposition (SFD). The method comprises exposing the substrate to a metal-carbonyl precursor gas, thereby forming a metal layer on the substrate from thermal decomposition of the metal-carbonyl precursor gas, subsequently exposing the metal layer to a reducing gas, and repeating the exposing steps until a metal layer with a desired thickness is formed. In one embodiment of the invention the metal-carbonyl precursor can be selected from at least one of W(CO)₆, Ni(CO)₄, Mo(CO)₆, Co₂(CO)₈, Rh₄(CO)₁₂, Re₂(CO)₁₀, Cr(CO)₆, and Ru₃(CO)₁₂, and the deposited metal layer can be at least one of W, Ni, Mo, Co, Rh, Re, Cr, and Ru, respectively.

In another embodiment of the invention, a method is provided for depositing a W layer on a substrate by exposing the substrate to a W(CO)₆ precursor gas, forming a W layer on the substrate from thermal decomposition of the W(CO)₆ precursor gas, subsequently exposing the W layer to a reducing gas, and repeating the exposing steps until a W layer with a desired thickness is formed.

### BRIEF DESCRIPTION OF THE DRAWINGS

In the accompanying drawings:

FIG. 1 is a simplified block-diagram of a processing system for depositing metal layers according to an embodiment of the present invention;

FIG. 2 is a flowchart for depositing a metal layer according to an embodiment of the invention;

FIG. 3 schematically shows gas flows during sequential flow deposition of a metal layer according to an embodiment of the invention;

FIG. 4 shows the number of nodules in a W layer as a function of W layer thickness according to an embodiment of the invention;

FIG. 5 shows the number of nodules in a W layer as a function of W layer thickness according to an embodiment of the invention;

FIG. 6A shows a cross-sectional SEM micrograph, and a schematic constructed from the micrograph, of a W layer deposited by CVD; and

FIG. 6B shows a cross-sectional SEM micrograph, and a schematic constructed from the micrograph, of a W layer deposited according to an embodiment of the invention.

### DETAILED DESCRIPTION OF SEVERAL EMBODIMENTS

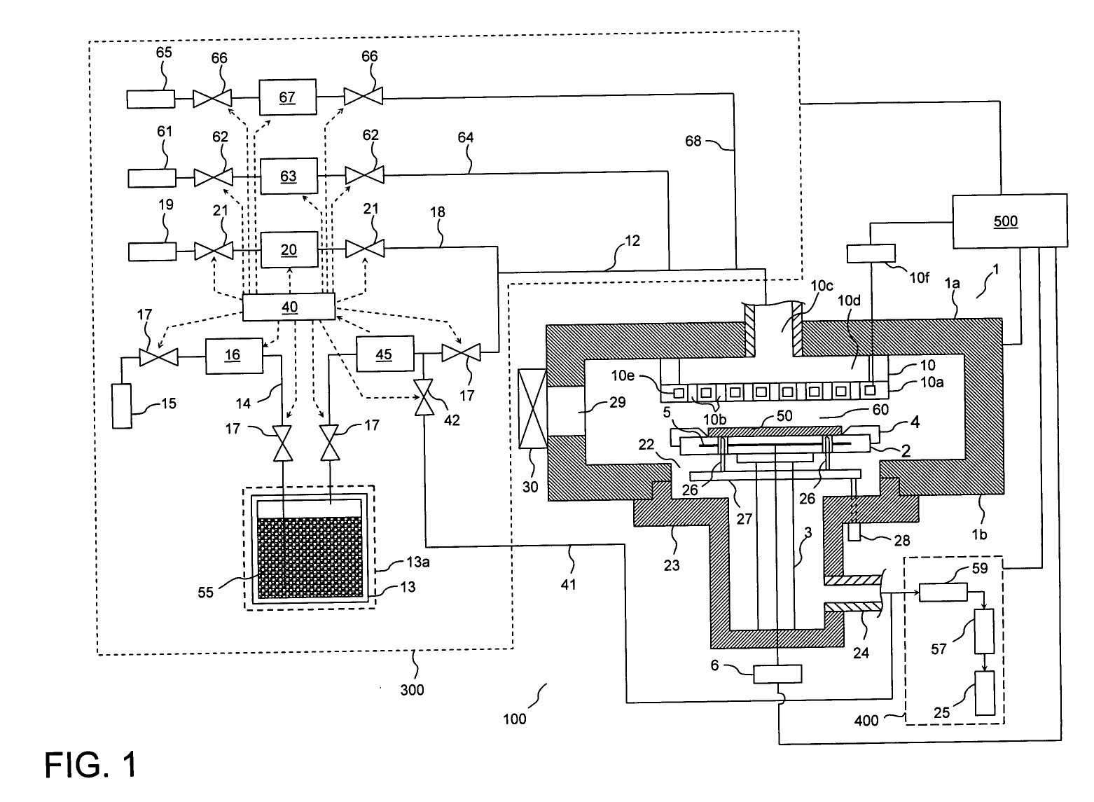

FIG. 1 is a simplified block-diagram of a processing system for depositing metal layers according to an embodiment of the present invention. The processing system 100 comprises a process chamber 1 that contains an upper chamber section 1a, a lower chamber section 1b, and an exhaust chamber 23. A circular opening 22 is formed in the middle of lower chamber section 1b, where bottom section 1b connects to exhaust chamber 23.

Provided inside process chamber 1 is a substrate holder 2 for horizontally holding a substrate (wafer) 50 to be processed. The substrate holder 2 is supported by a cylindrical support member 3, which extends upward from the center of the lower part of exhaust chamber 23. A guide ring 4 for positioning the substrate 50 on the substrate holder 2 is provided on the edge of substrate holder 2. Furthermore, the substrate holder 2 contains a heater 5 that is controlled by power source 6, and is used for heating the substrate 50. The heater 5 can be a resistive heater. Alternately, the heater 5 may be a lamp heater.

During processing, the heated substrate 50 thermally decomposes a W(CO)₆ precursor and enables deposition of a W layer on the substrate 50. The substrate holder 2 is heated to a pre-determined temperature that is suitable for depositing the desired W layer onto the substrate 50. A heater (not shown) is embedded in the walls of process chamber 1 to heat the chamber walls to a pre-determined temperature. The heater can maintain the temperature of the walls of process chamber 1 from about 40° C. to about 80° C.

A showerhead 10 is located in the upper chamber section 1a of process chamber 1. Showerhead plate 10a at the bottom of showerhead 10 contains multiple gas delivery holes 10b for delivering a process gas comprising the W(CO)₆ precursor gas into a processing zone 60 located above the substrate 50. The processing zone 60 is a volume defined by the substrate diameter and by the gap between the substrate 50 and the showerhead 10.

An opening 10c is provided in the upper chamber section 1b for introducing a process gas from gas line 12 into a gas distribution compartment 10d. Concentric coolant flow channels 10e are provided for controlling the temperature of the showerhead 10 and thereby preventing the decomposition of the W(CO)₆ precursor gas inside the showerhead 10. A coolant fluid such as water, can be supplied to the coolant flow channels 10e from a coolant fluid source 10f for controlling the temperature of showerhead 10 from about 20° C. to about 100° C.

The gas line 12 connects the precursor delivery system 300 to process chamber 1. A precursor container 13 contains a solid W(CO)₆ precursor 55, and a precursor heater 13a is provided for heating the precursor container 13 to maintain the W(CO)₆ precursor 55 at a temperature that produces a desired vapor pressure of the W(CO)₆ precursor. The W(CO)₆ precursor 55 advantageously can have a relatively high vapor pressure, Pᵥₐₚ˜1 Torr at 65° C. Therefore, only moderate heating of the precursor source 13 and the precursor gas delivery lines (e.g., gas line 12) is required for delivering the W(CO)₆ precursor gas to the process chamber 1. Furthermore, the W(CO)₆ precursor does not thermally decompose at temperatures below about 200° C. This can significantly reduce decomposition of the W(CO)₆ precursor due to interactions with heated chamber walls and gas phase reactions.

In one embodiment, W(CO)₆ precursor vapor can be delivered to the process chamber 1 without the use of a carrier gas or, alternatively, a carrier gas can be used to enhance the delivery of the precursor vapor to the process chamber 1. Gas line 14 can provide a carrier gas from gas source 15 to the precursor container 13, and a mass flow controller (MFC) 16 can be used to control the carrier gas flow. When a carrier gas is used, it may be introduced into the lower part of precursor container 13 so as to percolated through the solid W(CO)₆ precursor 55. Alternatively, the carrier gas may be introduced into the precursor source 13 and distributed across the top of the solid W(CO)₆ precursor 55. A sensor 45 is provided for measuring the total gas flow from the precursor container 13. The sensor 45 can, for example, comprise a MFC, and the amount of W(CO)₆ precursor delivered to the process chamber 1, can be determined using sensor 45 and mass flow controller 17. Alternatively, the sensor 45 can comprise a light absorption sensor to measure the concentration of the W(CO)₆ precursor in the gas flow to the process chamber 1.

A bypass line 41 is located downstream from sensor 45 and connects gas line 12 to exhaust line 24. Bypass line 41 provided for evacuating gas line 12 and for stabilizing the supply of the W(CO)₆ precursor to the process chamber 1. In addition, a valve 42, located downstream from the branching of gas line 12, is provided on bypass line 41

Heaters (not shown) are provided to independently heat gas lines 12, 14, and 41, where the temperatures of the gas lines can be controlled to avoid condensation of the W(CO)₆ precursor in the gas lines. The temperature of the gas lines can be controlled from about 20° C. to about 100° C., or from about 25° C. to about 60° C.

Dilution gases can be supplied from gas source 19 to gas line 12 using gas line 18. The dilution gases can be used to dilute the process gas or to adjust the process gas partial pressure(s). Gas line 18 contains a MFC 20 and valves 21. MFCs 16 and 20, and valves 17, 21, and 42 are controlled by controller 40, which controls the supply, shutoff, and the flow of a carrier gas, the W(CO)₆ precursor gas, and a dilution gas. Sensor 45 is also connected to controller 40 and, based on output of the sensor 45, controller 40 controls the carrier gas flow through mass flow controller 16 to obtain the desired W(CO)₆ precursor flow to the process chamber 1. A reducing gas can be supplied from gas source 61 to the process chamber 1 using gas line 64, MFC 63, and valves 62. A purge gas can be supplied from gas source 65 to process chamber 1 using gas line 68, MFC 67, and valves 66. Controller 40 controls the supply, shutoff, and the flow of the dilution gas and the purge gas.

Exhaust line 24 connects exhaust chamber 23 to vacuum pumping system 400. Vacuum pump 25 is used to evacuate process chamber 1 to the desired degree of vacuum and to remove gaseous species from the process chamber 1 during processing. An automatic pressure controller (APC) 59 and a trap 57 can be used in series with the vacuum pump 25. The vacuum pump 25 can include a turbo-molecular pump (TMP) capable of a pumping seed up to about 5000 liters per second (and greater). Alternatively, the vacuum pump 25 can include a dry pump. During processing, the process gas can be introduced into the process chamber 1 and the chamber pressure adjusted by the APC 59. The APC 59 can comprise a butterfly-type valve or a gate valve. The trap 57 can collect unreacted precursor material and by-products from the process chamber 1.

In the process chamber 1, three substrate lift pins 26 (only two are shown) are provided for holding, raising, and lowering the substrate 50. The substrate lift pins 26 are affixed to plate 27, and can be lowered to below to the upper surface of substrate holder 2. A drive mechanism 28 utilizing, for example, an air cylinder, provides means for raising and lowering the plate 27. A substrate 50 can be transferred in and out of process chamber 1 through gate valve 30 and chamber feed-through passage 29 via a robotic transfer system (not shown) and received by the substrate lift pins. Once the substrate 50 is received from the transfer system, it is lowered to the upper surface of the substrate holder 2 by lowering the substrate lift pins 26.

A processing system controller 500 includes a microprocessor, a memory, and a digital I/O port capable of generating control voltages sufficient to communicate and activate inputs of the processing system 100 as well as monitor outputs from the processing system 100. Moreover, the processing system controller 500 is coupled to and exchanges information with process chamber 1, precursor delivery system 300 that includes controller 40 and precursor heater 13a, vacuum pumping system 400, power source 6, and coolant fluid source l0f. In the vacuum pumping system 400, the processing system controller 500 is coupled to and exchanges information with the automatic pressure controller 59 for controlling the pressure in the process chamber 1. A program stored in the memory is utilized to control the aforementioned components of a processing system 100 according to a stored process recipe. One example of processing system controller 500 is a DELL PRECISION WORKSTATION 610™, available from Dell Corporation, Dallas, Tex.

A processing system for forming W layers can comprise a single wafer process chamber as shown and described in FIG. 1. Alternatively, the processing system can comprise a batch type process chamber capable of processing multiple substrates (wafers) simultaneously. In addition to semiconductor wafers, e.g., Si wafers, the substrates can, for example, comprise LCD substrates, glass substrates, or compound semiconductor substrates. The process chamber can process substrates of any size such as 200 mm substrates, 300 mm substrates, or even larger substrates. The metal layer can, for example, be deposited on SiO₂, Ta, TaN, Ti, TiN, or high-k layer layers, overlying a substrate.

In general, various metal layers can be deposited from the corresponding metal-carbonyl precursors. This includes deposition of W, Ni, Mo, Co, Rh, Re, Cr, and Ru metal layers from W(CO)₆, Ni(CO)₄, Mo(CO)₆, Co₂(CO)₈, Rh₄(CO)₁₂, Re₂(CO)₁₀, Cr(CO)₆, and Ru₃(CO)₁₂ precursors, respectively.

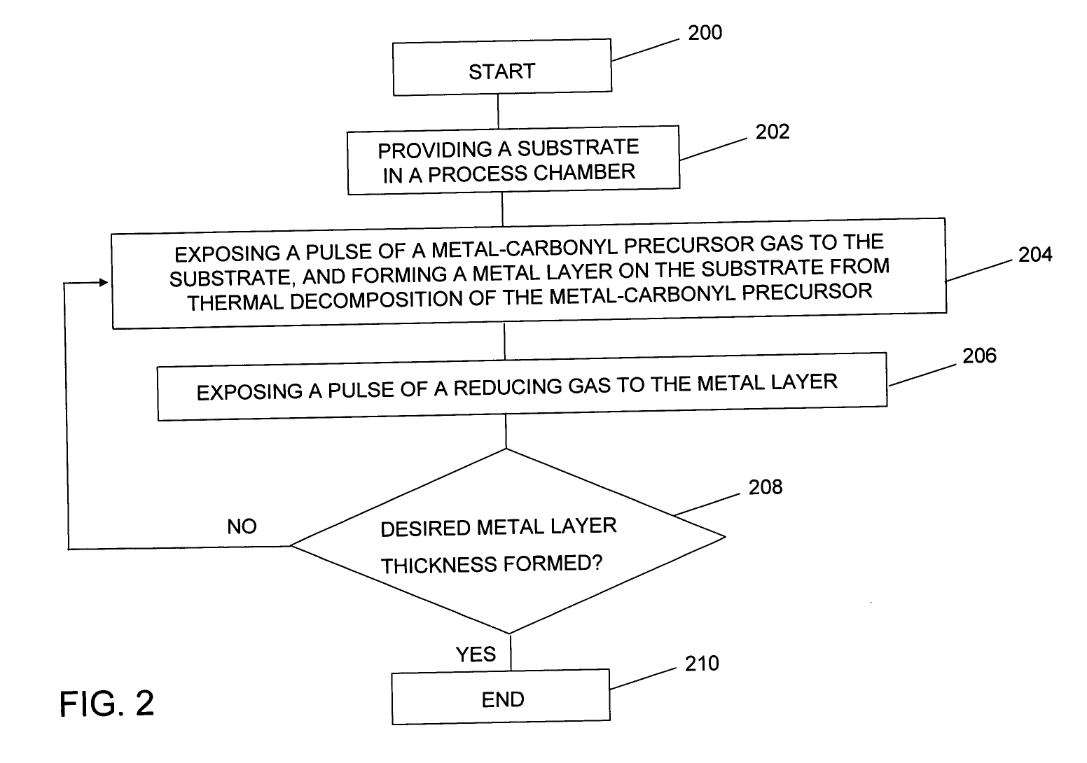

FIG. 2 is a flowchart for depositing a metal layer according to an embodiment of the invention. At 200, the process is started. At 202, a substrate is provided in a process chamber, and the substrate is heated to a pre-determined temperature by the substrate holder. At 204, the substrate is exposed to a metal-carbonyl precursor gas and a metal layer is formed on the substrate from thermal decomposition of the metal-carbonyl precursor. At 206, the metal layer is exposed to a reducing gas. At 208, a decision is made to either repeat the process and deposit a thicker metal layer, or, if a desired metal layer thickness is formed, to end the process at 210.

In principle, a reducing gas is not needed for thermally depositing metal layers from metal-carbonyl precursors, because the metal atom in the metal-carbonyl precursor is already zero-valent. Thermal decomposition of metal-carbonyl precursors and subsequent metal deposition on a substrate, proceeds predominantly by CO elimination and desorption of CO by-products from the substrate. Incorporation of CO by-products into the metal layers can result from incomplete decomposition of the metal-carbonyl precursor, incomplete removal of adsorbed CO by-products from metal layer, and re-adsorption of CO by-products from the process chamber onto the metal layer. Incorporation of CO reaction by-products into a metal layer can increase the (electrical) resistivity of the metal layer and lead to poor surface morphology due to abnormal growth of nodules (metal particles) on the surface of metal layer and/or in the metal layer.

A thin metal layer that is between about 5 A and about 60 A thick is deposited on a substrate by exposing the substrate to a metal-carbonyl precursor gas comprising a metal-carbonyl precursor and optionally a carrier gas and a dilution gas. Thereafter, the deposited metal layer is exposed to a reducing gas, and optionally a dilution gas, to aid in the removal of CO by-products and impurities from the deposited metal layer. Following the exposure of a reducing gas to the metal layer, the deposition of the metal layer can be repeated if a thicker metal layer is desired, or if the desired metal layer thickness is formed, the deposition process can be ended. It should be noted that the term chemical vapor deposition (CVD) is used for a non-cyclical deposition process, i.e. where the substrate is exposed to a metal-carbonyl precursor gas only once during the metal deposition process.

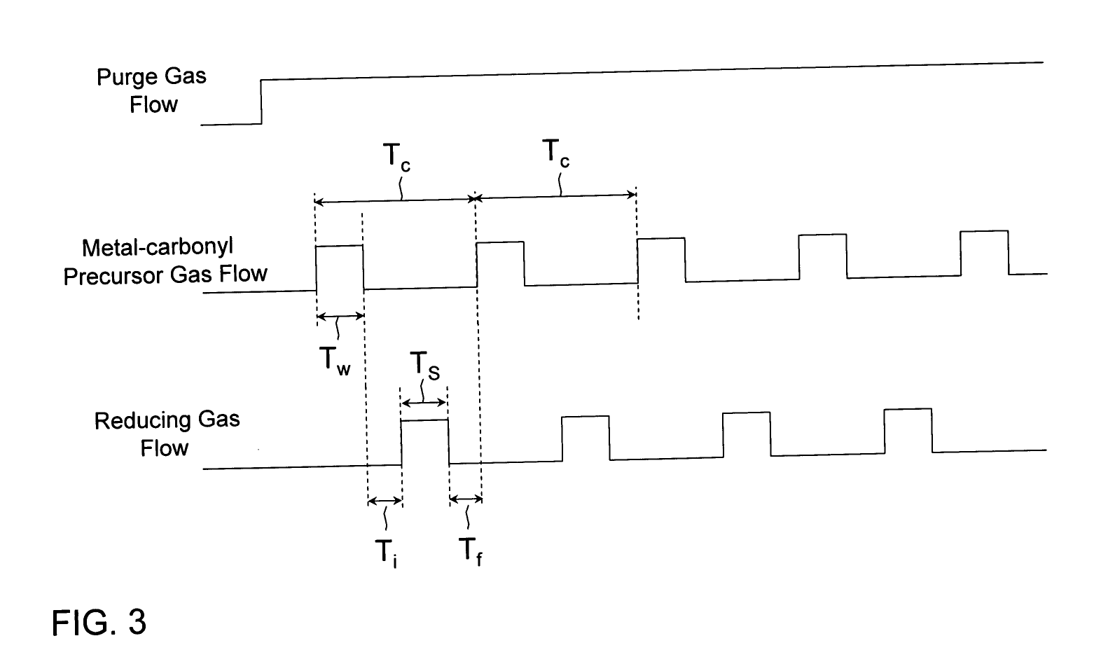

FIG. 3 schematically shows gas flows during sequential flow deposition of a metal layer according to an embodiment of the invention. In the embodiment illustrated in FIG. 3, a purge gas, e.g., Ar, is introduced into the process chamber and is continuously flowed during the deposition process. The flow rate of the purge gas can be constant during the sequential flow deposition process, or the flow rate can be varied during the sequential flow deposition process. The purge gas can be selected to efficiently remove reactants (e.g., metal-carbonyl precursor and reducing gas) and reaction by-products from the process chamber. The purge gas can, for example, comprise in inert gas such as Ar, He, Kr, Xe, and N₂. During the deposition process, a metal-carbonyl precursor gas and a reducing gas are alternately flowed into the process chamber to be exposed to the substrate. The metal-carbonyl precursor gas can further comprise a carrier gas and a dilution gas. In addition, the reducing gas can further comprise a dilution gas. The carrier and dilution gases can, for example, comprise inert gases such as Ar, He, Kr, Xe, and N₂. During the deposition process, gases are continuously being exhausted from the process chamber using a vacuum pumping system.

Continuing with FIG. 3, after the purge gas flow is created in the process chamber, a metal-carbonyl precursor gas is flowed into the process chamber for a predetermined time period T_{w}. The length of time period T_{w} is selected to deposit a metal layer with a desired layer thickness. The length of time period T_{w} can, for example, depend on the reactivity of the metal-carbonyl precursor, dilution of the metal-carbonyl precursor with an inert gas, and the flow characteristics of the processing system. At the end of time period T_{w}, the metal-carbonyl precursor gas flow is interrupted, and the processing system is purged for a time period Tᵢ by a purge gas and optionally a dilution gas.

At the end of time period Tᵢ, a reducing gas is flowed into the process chamber for a predetermined time period Tₛ. The time period Tₛ is selected to be long enough to expose a sufficient amount of reducing gas to interact with and to aid in the removal of by-products from the metal layer surface. In general, the reducing gas can comprise a gas that is capable of aiding in the removal of reaction by-products from the metal layer. The reducing gas can, for example, comprise a silicon-containing gas such as silane (SiH₄), disilane (Si₂H₆), and dichlorosilane (SiCl₂H₂). Alternatively, the reducing gas can comprise a boron-containing gas, for example a boron-containing gas with the general formula BₓH₃ₓ. This includes, for example, borane (BH₃), diborane (B₂H₆), triborane (B₃H₉), and others. Alternately, the reducing gas can comprise a nitrogen-containing gas, for example, ammonia (NH₃). In addition, the reducing gas can comprise more than one of the abovementioned gases.

At the end of time period Tₛ, the reducing gas flow is interrupted, and the processing system is purged for a time period T_{f} by a purge gas and optionally a dilution gas. Time periods Tᵢ and T_{f} can be equal in length, or they can vary in length.

In the sequential flow deposition process schematically shown in FIG. 3, a deposition cycle T_{c} consists of time periods T_{w}, Tᵢ, Tₛ, and T_{f}. During time period T_{w}, a thin metal layer is deposited onto the substrate from thermal decomposition of the metal-carbonyl precursor; during time period Tᵢ, the process chamber is purged of the metal-carbonyl precursor and reaction by-products, e.g., CO; during time period Tₛ, the metal layer that was deposited during time period T_{w} is exposed to a reducing gas to aid in the removal of reaction by-products from the metal layer; and during time period T_{f}, the process chamber is purged of the reducing gas and any by-products. As described above, the sequential flow deposition process can be repeated to form a metal layer with a desired thickness.

Suitable process conditions that enable deposition of a metal layer with a desired thickness can be determined by direct experimentation and/or design of experiments (DOE). Adjustable process parameters can, for example, comprise the length of time periods T_{w}, Tᵢ, Tₛ, and T_{f}, temperature (e.g., substrate temperature), process pressure, process gases and relative gas flows of the process gases. The length of each period T_{w}, Tᵢ, Tₛ, and T_{f}, can be independently varied to optimize the properties of the metal layer. The length of each time period T_{w}, Tᵢ, Tₛ, and T_{f} can be the same in each deposition cycle, or alternatively, the length of each time period can vary in different deposition cycles. In general, the time period T_{w} can be between about 1 sec and about 500 sec, for example about 10 sec; the time period Tₛ can be between about 1 sec and about 120 sec; for example about 5 sec; and the time periods Tᵢ and T_{f} can be less than about 120 sec, for example about 30 sec.

In an alternative embodiment of the invention, the purge gas can be sequentially flowed into the process chamber when one of a metal-carbonyl precursor gas and a reducing gas are not flowing, for example during time periods Tᵢ and T_{f}. In an alternative embodiment of the invention, a purge gas can be omitted from the deposition process.

In one example, a W layer can be formed by the sequential flow deposition illustrated in the FIG. 2, using a W(CO)₆ precursor gas, a SiH₄ reducing gas, an Ar carrier gas, an Ar dilution gas, and an Ar purge gas. A W(CO)₆ gas flow rate can, for example, be less than about 4 sccm, a SiH₄ reducing gas flow rate can, for example, be less than about 500 sccm, and an Ar carrier gas flow rate can, for example, be between about 50 sccm and about 500 sccm, or between about 50 sccm and about 200 sccm. Ar dilution gas flow rate during W(CO)₆ gas flow can, for example, be between about 50 sccm and about 1000 sccm, or between about 50 sccm and about 500 sccm. An Ar dilution gas flow rate during SiH₄ gas flow can, for example, be between about 50 sccm and about 2000 sccm, or between about 100 sccm and about 1000 sccm. Ar purge gas flow rate can, for example, be between about 100 sccm and about 1000 sccm. The processing pressure in the process chamber can, for example, be less than about 5 Torr, or about 0.2 Torr, and the substrate temperature can be between about 200° C. and about 600° C., for example about 410° C. The time periods T_{w}, Tᵢ, Tₛ, and T_{f} can, for example, be about 6 sec, about 30 sec, about 10 sec, and about 30 sec, respectively.

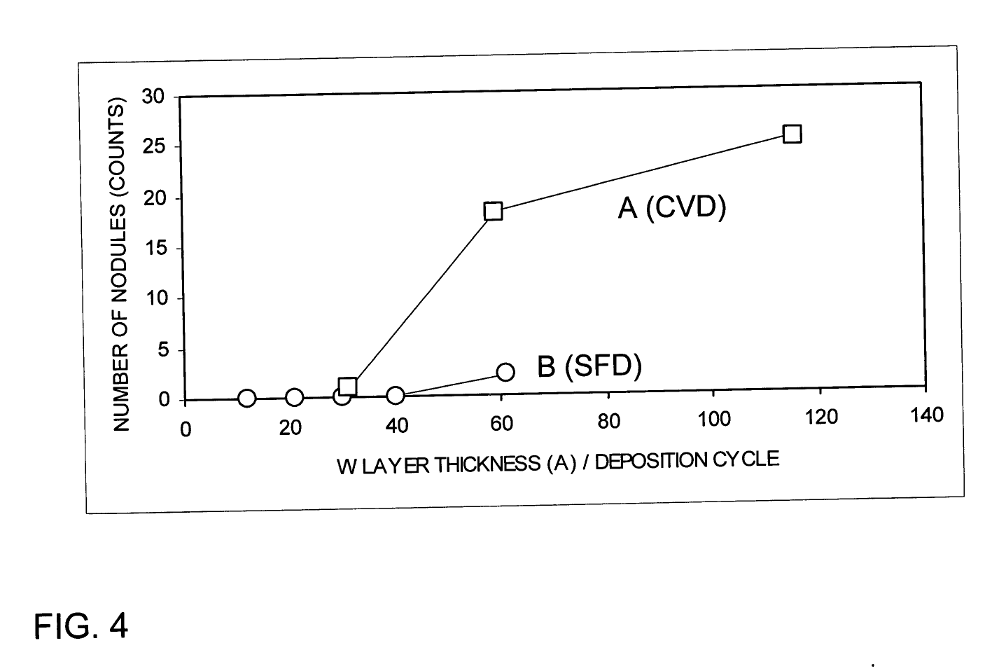

FIG. 4 shows the number of nodules in a W layer as a function of W layer thickness according to an embodiment of the invention. In FIG. 4, the number of nodules formed in W layers was visually observed over a 250 nm×250 nm area using SEM micrographs. Curve A shows the number of nodules observed in W layers deposited by CVD using W(CO)₆ gas, Ar carrier gas, and Ar dilution gas. The deposition conditions included a substrate temperature of about 410° C., a chamber pressure of about 0.3 Torr, an Ar carrier gas flow rate of about 90 sccm, and Ar dilution gas flow rate of about 250 sccm. Few nodules were observed by SEM until the W layer thickness exceeded about 30 A. When the W layer thickness was about 60 A, and greater, a large number of nodules were observed in the W layer. Accordingly, when using CVD, the W layer thickness should not exceed about 30 A in order to deposit a W layer with few nodules.

In FIG. 4, curve B shows the number of nodules that were observed in a W layer deposited by sequential flow deposition. The W layers were deposited using five deposition cycles (see T_{c} in FIG. 2), where an average of about 12, about 21, about 30, about 40, and about 61 A of W were deposited on the substrate in each deposition cycle. Ar was used as carrier gas, reducing gas, and purge gas, and the reducing gas was SiH₄. No nodules were observed in the W layers when deposited by sequential flow deposition when the W layer thickness per deposition cycle is about 40 A or less. When the W layer thickness per deposition cycle was about 40 A, few nodules were observed. Comparison of curves A and B in FIG. 4, illustrates that the use of sequential flow deposition, can greatly improve the surface morphology of a W layer that is thicker than about 30 A, by suppressing the formation of nodules in the W layer. The improved surface morphology is, for example, desirable when subsequent processing, following W layer formation, deposits materials into vias or contact holes by sputtering or plasma-enhanced CVD.

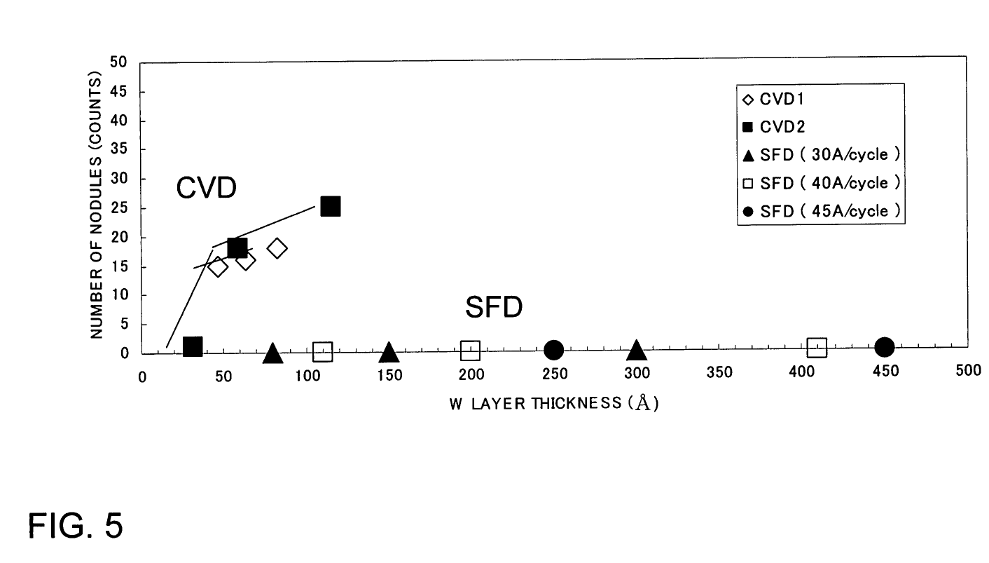

FIG. 5 shows the number of nodules in a W layer as a function of W layer thickness according to an embodiment of the invention. In FIG. 5, the number of nodules formed in W layers was visually observed over a 250 nm×250 nm area using SEM micrographs. In FIG. 5, the horizontal axis shows the total thickness of the deposited W layer. For example, the W layer with a thickness of about 200 A was deposited using 5 deposition cycles of about 40 A of W per deposition cycle, and the W layer with a thickness of about 450 A was deposited using 10 deposition cycles of about 45 A of W per deposition cycle.

Furthermore, FIG. 5 also shows the number of nodules observed in W layers deposited by CVD. The CVD conditions included a substrate temperature of about 410° C., and a chamber pressure of about 0.3 Torr. The Ar carrier gas flow rate was about 90 sccm and the dilution gas flow rate was about 250 sccm in runs CVD1 (▪); whereas the Ar carrier gas flow rate was about 100 sccm and the Ar dilution gas flow rate was about 800 sccm in runs CVD2 (⋄). Comparison of the number of nodules observed in W layer deposited by CVD and by SFD, illustrates that the use of SFD can greatly improve the surface morphology of a W layer that is thicker than about 30 A, and SFD allows deposition thick W layers with good surface morphology.

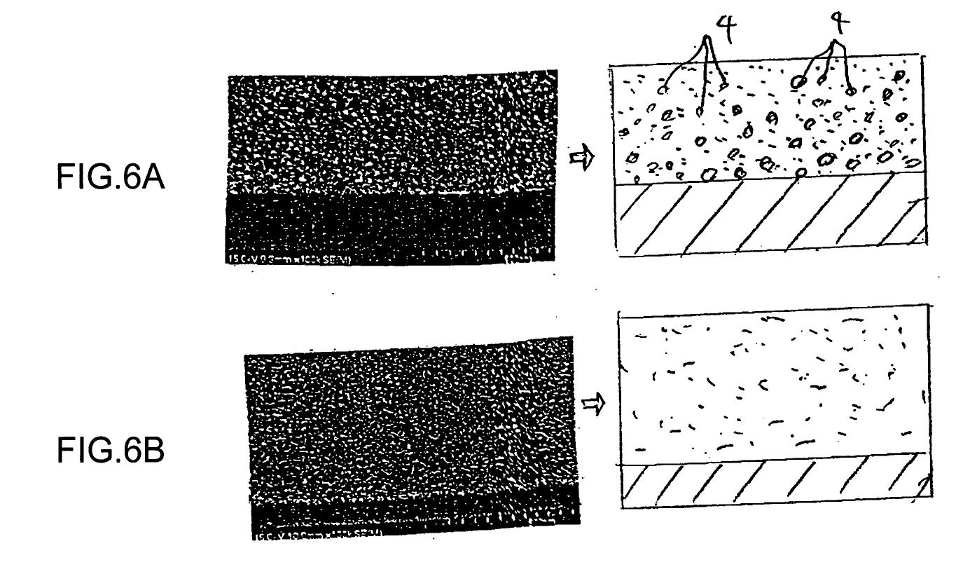

FIG. 6A shows a cross-sectional SEM micrograph, and a schematic constructed from the micrograph, of a W layer deposited by CVD. FIG. 6A shows a W layer with poor surface morphology due to multiple W nodules 4 that are observed in the W layer. FIG. 6B shows a cross-sectional SEM micrograph, and a schematic constructed from the micrograph, of a W layer deposited by SFD according to an embodiment of the invention. The W layer was deposited by the SFD method described in FIG. 3, where a W(CO)₆ precursor gas and a reducing gas comprising SiH₄, are alternately flowed in the process chamber. FIG. 6B shows a W layer with good surface morphology where few or no nodules are observed in the W layer.

In addition to W deposition onto flat substrates, sequential flow deposition of W layers on microstructures with high aspect ratios, resulted in W layers with improved morphology compared to W layers deposited by CVD. In one example, a W layer was deposited onto a via microstructure with an aspect ratio of about 5:1(height of the microstructure divided by the width of the microstructure) using sequential flow deposition with 10 deposition cycles at a substrate temperature of about 410° C. W(CO)₆ was used as a W precursor, Ar gas was used as a carrier gas (e.g., a flow rate of about 100 sccm) and Ar gas was used as a dilution gas (e.g., a flow rate of about 800 sccm). Furthermore, SiH₄ was used as a reducing gas, and the process pressure was maintained at about 0.3-0.4 Torr. The step coverage of the W layer deposited by sequential flow deposition was about 0.4 (thickness of the W layer on the sidewall of the microstructure near the bottom of the microstructure divided by the thickness of the W layer on the substrate away from the microstructure).

It should be understood that various modifications and variations of the present invention may be employed in practicing the invention. It is therefore to be understood that, within the scope of the appended claims, the invention may be practiced otherwise than as specifically described herein.

1. A method of depositing a metal layer on a substrate, the method comprising:
a) providing a substrate in a process chamber;
b) exposing the substrate to a metal-carbonyl precursor gas;
c) forming a metal layer on the substrate from thermal decomposition of the metal-carbonyl precursor gas;
d) exposing the metal layer to a reducing gas; and
e) repeating said exposing of said substrate, said forming and said exposing of said metal layer until a metal layer with a desired thickness is formed.

2. The method according to claim 1, wherein the metal-carbonyl precursor comprises at least one of W(CO)₆, Ni(CO)₄, Mo(CO)₆, Co₂(CO)₈, Rh₄(CO)₁₂, Re₂(CO)₁₀, Cr(CO)₆, and Ru₃(CO)₁₂.

3. The method according to claim 1, wherein the metal layer comprises at least one of W, Ni, Mo, Co, Rh, Re, Cr, and Ru.

4. The method according to claim 1, wherein a flow rate of the metal-carbonyl precursor is less than about 4 sccm.

5. The method according to claim 1, wherein the metal-carbonyl precursor gas further comprises at least one of a dilution gas and a carrier gas.

6. The method according to claim 5, wherein the at least one of a dilution gas and a carrier gas comprises an inert gas.

7. The method according to claim 6, wherein the inert gas comprises at least one of Ar, He, Kr, Xe, and N₂.

8. The method according to claim 5, wherein the precursor gas includes a carrier gas having a flow rate between about 50 sccm and about 500 sccm.

9. The method according to claim 8, wherein a flow rate of the carrier gas is between about 50 sccm and about 200 sccm.

10. The method according to claim 5, wherein a the precursor gas includes a dilution gas having a flow rate between about 50 sccm and about 1000 sccm.

11. The method according to claim 10, wherein a flow rate of the dilution gas is between about 50 sccm and about 500 sccm.

12. The method according to claim 1, wherein the metal-carbonyl precursor flow is between about 1 sec and about 500 sec.

13. The method according to claim 1, wherein the reducing gas comprises at least one of a silicon-containing gas, a boron-containing gas, and a nitrogen-containing gas.

14. The method according to claim 13, wherein reducing gas comprises at least one of SiH₄, Si₂H₆, and SiCl₂H₂.

15. The method according to claim 13, wherein the reducing gas comprises at least one of BH₃, B₂H₆, and B₃H₉.

16. The method according to claim 13, wherein the reducing gas comprises NH₃.

17. The method according to claim 1, wherein a flow rate of the reducing gas is less than about 500 sccm.

18. The method according to claim 1, wherein the reducing gas flow is between about 1 sec and about 120 sec.

19. The method according to claim 1, wherein the reducing gas further comprises a dilution gas.

20. The method according to claim 19, wherein the dilution gas comprises an inert gas.

21. The method according to claim 20, wherein the inert gas comprises at least one of Ar, He, Kr, Xe, and N₂.

22. The method according to claim 19, wherein a flow rate of the dilution gas is between about 50 sccm and about 2000 sccm.

23. The method according to claim 22, wherein a flow rate of the dilution gas is between about 100 sccm and about 1000 sccm.

24. The method according to claim 1, wherein the metal-carbonyl precursor gas and the reducing gas are sequentially flowed into the process chamber.

25. The method according to claim 1, further comprising flowing a purge gas in the process chamber.

26. The method according to claim 25, wherein the purge gas comprises an inert gas.

27. The method according to claim 26, wherein the inert gas comprises at least one of Ar, He, Kr, Xe, and N₂.

28. The method according to claim 25, wherein the purge gas is continuously flowed in the process chamber.

29. The method according to claim 25, wherein the purge gas is flowed in the process chamber prior to at least one of said exposing of said substrate and said exposing of said metal layer.

30. The method according to claim 29, wherein the purge gas is flowed for less than about 120 sec prior to at least one of said exposing of said substrate and said exposing of said metal layer.

31. The method according to claim 25, wherein a flow rate of the purge gas is between about 100 sccm and 1000 sccm.

32. The method according to claim 1, wherein the substrate temperature is between about 200° C. and about 600° C.

33. The method according to claim 1, wherein a process chamber pressure is less than about 5 Torr.

34. The method according to claim 1, wherein the thickness of the metal layer deposited in one deposition cycle is between about 5 A and about 60 A.

35. The method according to claim 34, wherein the thickness of the metal layer deposited in one deposition cycle is between about 15 A and about 30 A.

36. The method according to claim 1, wherein the substrate comprises at least one of a semiconductor substrate, a LCD substrate, and a glass substrate.

37. The method according to claim 36, wherein the semiconductor substrate comprises at least one of Si, SiO₂, Ta, TaN, Ti, TiN, and high-k.

38. A method of depositing a W layer on a substrate, the method comprising:
a) providing a substrate in a process chamber;
b) exposing the substrate to a W(CO)₆ precursor gas;
c) forming a W layer on the substrate from thermal decomposition of the W(CO)₆ precursor gas;
d) exposing the W layer to a reducing gas; and
e) repeating said exposing of said substrate, said forming and said exposing of said W layer until a W layer with a desired thickness is formed.

39. The method according to claim 38, wherein a flow rate of the W(CO)₆ precursor is less than about 4 sccm.

40. The method according to claim 38, wherein the W(CO)₆ precursor gas further comprises at least one of a dilution gas and a carrier gas.

41. The method according to claim 40, wherein the at least one of a dilution gas and a carrier gas comprises an inert gas.

42. The method according to claim 41, wherein the inert gas comprises at least one of Ar, He, Kr, Xe, and N₂.

43. The method according to claim 41, wherein the precursor gas includes the carrier gas having a flow rate between about 50 sccm and about 500 sccm.

44. The method according to claim 43, wherein a flow rate of the carrier gas is between about 50 sccm and about 200 sccm.

45. The method according to claim 41, wherein the precursor gas includes the dilution gas having a flow rate between about 50 sccm and about 1000 sccm.

46. The method according to claim 45, wherein a flow rate of the dilution gas is between about 50 sccm and about 500 sccm.

47. The method according to claim 38, wherein the W(CO)₆ precursor flow is between about 1 sec and about 500 sec.

48. The method according to claim 38, wherein the reducing gas comprises at least one of a silicon-containing gas, a boron-containing gas, and a nitrogen-containing gas.

49. The method according to claim 48, wherein the reducing gas comprises at least one of SiH₄, Si₂H₆, and SiCl₂H₂.

50. The method according to claim 48, wherein the reducing gas comprises at least one of BH₃, B₂H₆, and B₃H₉.

51. The method according to claim 48, wherein the reducing gas comprises NH₃.

52. The method according to claim 38, wherein a flow rate of the reducing gas is less than about 500 sccm.

53. The method according to claim 38, wherein the reducing gas flow is between about 1 sec and about 120 sec.

54. The method according to claim 38, wherein the reducing gas further comprises a dilution gas.

55. The method according to claim 54, wherein the dilution gas comprises an inert gas.

56. The method according to claim 55, wherein the inert gas comprises at least one of Ar, He, Kr, Xe, and N₂.

57. The method according to claim 54, wherein a flow rate of the dilution gas is between about 50 sccm and about 2000 sccm.

58. The method according to claim 57, wherein a flow rate of the dilution gas is between about 100 sccm and about 1000 sccm.

59. The method according to claim 38, wherein the W(CO)₆ precursor and the reducing gas are sequentially flowed into the process chamber.

60. The method according to claim 38, further comprising flowing a purge gas in the process chamber.

61. The method according to claim 60, wherein the purge gas comprises an inert gas.

62. The method according to claim 61, wherein the inert gas comprises at least one of Ar, He, Kr, Xe, and N₂.

63. The method according to claim 60, wherein the purge gas is continuously flowed in the process chamber.

64. The method according to claim 60, wherein the purge gas is flowed in the process chamber prior to at least one said exposing of said substrate and said exposing of said W layer.

65. The method according to claim 64, wherein the purge gas is flowed for less than about 120 sec prior to at least one of said exposing of said substrate and said exposing of said W layer.

66. The method according to claim 60, wherein a flow rate of the purge gas is between about 100 sccm and about 1000 sccm.

67. The method according to claim 38, wherein the substrate temperature is between about 200° C. and about 600° C.

68. The method according to claim 67, wherein the substrate temperature is about 410° C.

69. The method according to claim 38, wherein a process chamber pressure is less than about 5 Torr.

70. The method according to claim 69, wherein a process chamber pressure is about 0.2 Torr.

71. The method according to claim 38, wherein the thickness of the W layer deposited in one deposition cycle is between about 5 A and about 60 A.

72. The method according to claim 71, wherein the thickness of the W layer deposited in one deposition cycle is between about 15 A and about 30 A.

73. The method according to claim 38, wherein the substrate comprises at least one of a semiconductor substrate, a LCD substrate, and a glass substrate.

74. The method according to claim 73, wherein the semiconductor substrate comprises at least one of Si, SiO₂, Ta, TaN, Ti, TiN, and high-k.
